(19) United States
(12) Patent Application Publication
(10) Pub. No.: US 2020/0203192 A1
(43) Pub. Date: Jun. 25, 2020

(54) BACKSIDE BRUSH FOR CLEANING WAFER AND CLEANING APPARATUS HAVING THE SAME

(71) Applicant: XIA TAI XIN SEMICONDUCTOR (QING DAO) LTD., Qingdao (CN)

(72) Inventor: YONG-SEOK RO, Singapore (SG)

(21) Appl. No.: 16/661,955

(22) Filed: Oct. 23, 2019

Related U.S. Application Data
(60) Provisional application No. 62/779,475, filed on Dec. 14, 2018.

(51) Int. Cl. H01L 21/67; H01L 21/02; B08B 1/00; B08B 3/04; B08B 1/04

(52) U.S. Cl. CPC H01L 21/67046; H01L 21/02065; H01L 21/02074; B08B 1/04; B08B 1/002; B08B 3/04; H01L 21/02096

(57) ABSTRACT

The present disclosure provides a backside brush for cleaning a backside of a wafer. The backside of the wafer has a central region and a periphery region surrounding the central region. The backside brush includes a backside brush core and a backside brush pad covering an outer surface of the backside brush core. The backside brush pad includes a soft pad and an abrasive pad. The soft pad of the backside brush pad covers a portion of the outer surface the backside brush core and is configured to brush the central region of the backside of the wafer. The abrasive pad of the backside brush pad covers another portion of the outer surface of the backside brush core and is configured to brush the periphery region of the backside of the wafer.

### CROSS-REFERENCE TO RELATED APPLICATION

This application claims the benefit of and priority to U.S. Provisional Patent Application No. 62/779,475 filed on Dec. 14, 2018, the contents of which are incorporated fully by reference herein.

### FIELD

The present disclosure generally relates to a backside brush for cleaning a wafer and a cleaning apparatus having the same. More specifically, the present disclosure relates to a backside brush having a soft pad and an abrasive pad for cleaning a backside of a wafer.

### BACKGROUND

A chemical mechanical polishing or chemical mechanical planarization (CMP) process is accomplished by holding a semiconductor wafer against a rotating polishing surface, or moving the wafer relative to the polishing surface, under controlled conditions of temperature, pressure, and chemical composition. The polishing surface, which may be a planar pad formed of a relatively soft and porous material (e.g., a blown polyurethane), is soaked with a chemically reactive and abrasive aqueous slurry. The aqueous slurry, which may be either acidic or basic, typically includes abrasive particles, reactive chemical agents such as a transition metal chelated salt or an oxidizer, and adjuvants such as solvents, buffers, and passivating agents. In such a slurry, salt or other agents may facilitate chemical etching actions, while the abrasive particles and the polishing pad together may facilitate provide the mechanical polishing actions.

The CMP process is becoming the main planarization technique for planarizing both dielectric and metal layers. For the CMP of a dielectric layer, such as borophosphosilicate glass (BPSG), borophosphorous tetraethyl orthosilicate (BPTEOS), and plasma-enhanced chemical vapor deposition (PECVD) oxides, a fumed silica-based slurry is normally used. Other types of slurries, such as dispersed silica, fumed and dispersed alumina, may also be used for CMP of both dielectric layers and metal layers (such as tungsten or titanium). When a CMP process is completed, the wafer's surfaces are covered in particles (referred to as a slurry residues). At later actions in the process flow, if the slurry residues are allowed to be remained on or even redistributed across the surfaces of the wafer, contamination issue may occur, which would result in a loss in die yield and/or device performance To prevent contamination, all surfaces of the wafer must be free of slurry residues after the CMP process.

Accordingly, there remains a need in the art to provide a cleaning device to improve the cleaning process of a wafer after a CMP process.

### SUMMARY

In view of above, an object of the present disclosure is to provide a backside for cleaning a wafer and a cleaning apparatus to improve a cleaning process of the wafer.

To achieve the above object, an implementation of the present disclosure provides a backside brush for cleaning a backside of a wafer. The backside of the wafer has a central region and a periphery region surrounding the central region. The backside brush includes a backside brush core and a backside brush pad covering an outer surface of the backside brush core. The backside brush pad includes a soft pad and an abrasive pad. The soft pad of the backside brush pad covers a portion of the outer surface the backside brush core and is configured to brush the central region of the backside of the wafer. The abrasive pad of the backside brush pad covers another portion of the outer surface of the backside brush core and is configured to brush the periphery region of the backside of the wafer.

To achieve the above object, another implementation of the present disclosure provides a cleaning apparatus for cleaning a wafer. The cleaning apparatus includes a frontside brush for cleaning a frontside of the wafer and a backside brush for cleaning a backside of the wafer. The frontside brush includes a frontside brush core and a frontside brush pad covering an outer surface of the frontside brush core. The backside of the wafer has a central region and a periphery region surrounding the central region. The backside brush includes a backside brush core and a backside brush pad covering an outer surface of the backside brush core. The backside brush pad includes a soft pad and an abrasive pad. The soft pad of the backside brush pad covers a portion of the outer surface the backside brush core and is configured to brush the central region of the backside of the wafer. The abrasive pad of the backside brush pad covers another portion of the outer surface of the backside brush core and is configured to brush the periphery region of the backside of the wafer.

To achieve the above object, yet another implementation of the present disclosure provides a method of cleaning a wafer. In a first action of the method, the wafer is loaded between a frontside brush and a backside brush of a cleaning apparatus. In a second action of the method, the frontside of the wafer is brushed by the frontside brush of the cleaning apparatus. In a third action of the method, the backside of the wafer is brushed by the backside brush of the cleaning apparatus. A periphery region of the backside of the wafer is brushed by an abrasive pad of the backside brush, and a central region of the backside of the wafer is brushed by a soft pad of the backside brush.

As describe above, the backside brush of the cleaning apparatus of the implementations of the present disclosure includes a soft pad for cleaning a central region of a backside of a wafer and an abrasive pad for cleaning a periphery region of the backside of the wafer. Metal particles and carbon particles attached to the periphery region of the backside of the wafer after manufacturing processes (such as chemical mechanical polishing or etching) can be removed by the abrasive pad of the backside brush of the present disclosure without further chemical cleaning processes. The backside brush of the present disclosure can improve the performance of the cleaning process for the wafer.

### BRIEF DESCRIPTION OF THE DRAWINGS

Implementations of the present technology will now be described, by way of example only, with reference to the attached figures.

FIG. 1A is a schematic diagram of a cleaning apparatus for cleaning a wafer according to an implementation of the present disclosure.

FIG. 1B is a schematic diagram showing a frontside brush and a backside brush of the cleaning apparatus of FIG. 1A.

FIG. 1C is a schematic diagram showing a backside of the wafer of FIGS. 1A and 1B.

FIGS. 1D and 1E are exploded views of the frontside brush and the backside brush of FIG. 1B.

FIG. 1F is a schematic diagram of the backside brush of the cleaning apparatus of FIG. 1A according to another implementation of the present disclosure.

FIG. 2 is a flowchart of a method of cleaning a wafer according to an implementation of the present disclosure.

### DETAILED DESCRIPTION

The present disclosure will now be described more fully hereinafter with reference to the accompanying drawings, in which exemplary implementations of the disclosure are shown. This disclosure may, however, be embodied in many different forms and should not be construed as limited to the exemplary implementations set forth herein. Rather, these exemplary implementations are provided so that this disclosure will be thorough and complete, and will fully convey the scope of the disclosure to those skilled in the art. Like reference numerals refer to like elements throughout.

The terminology used herein is for the purpose of describing particular exemplary implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

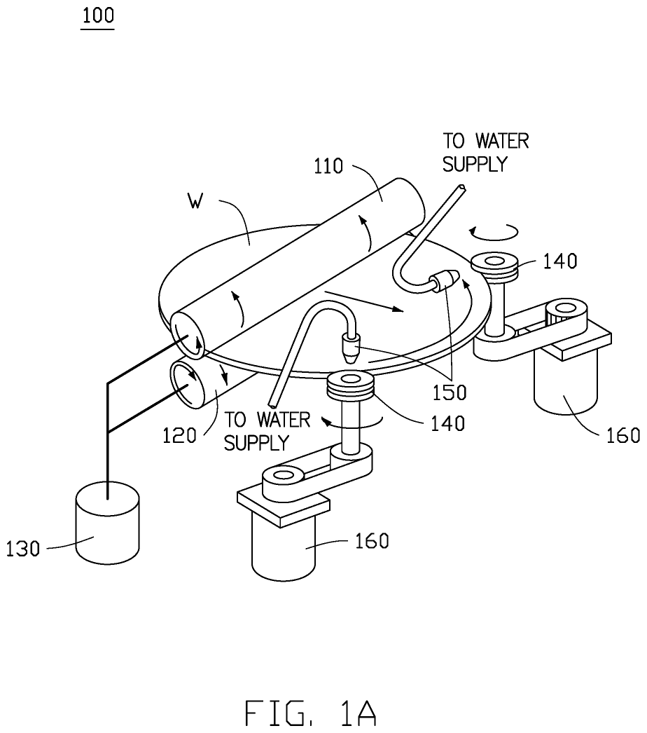

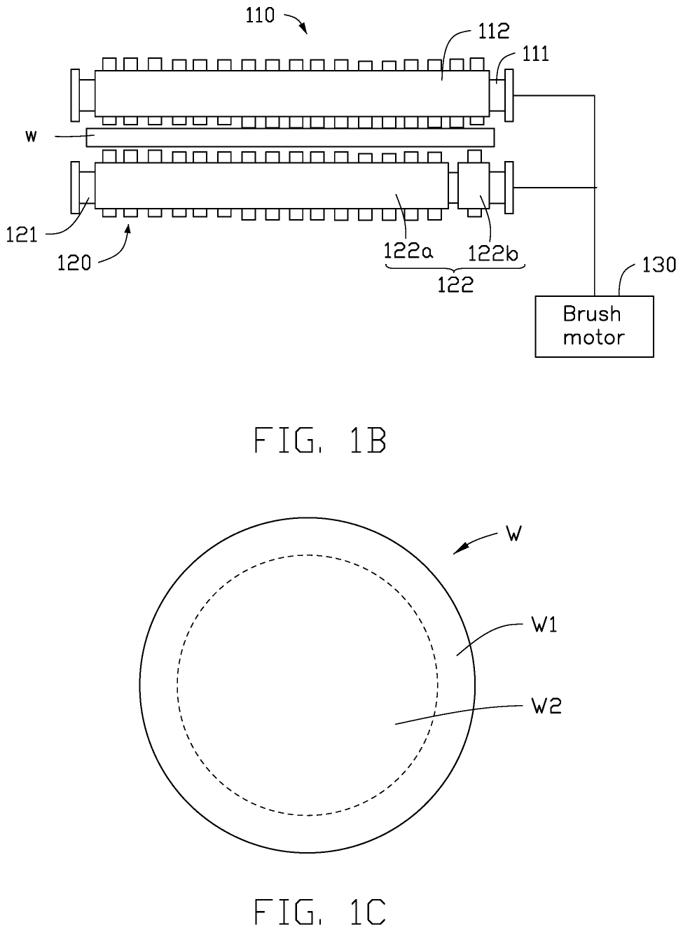

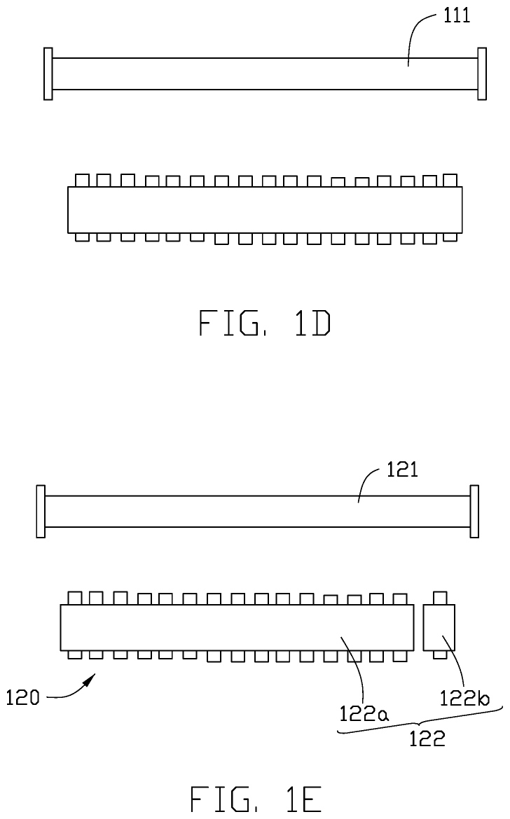

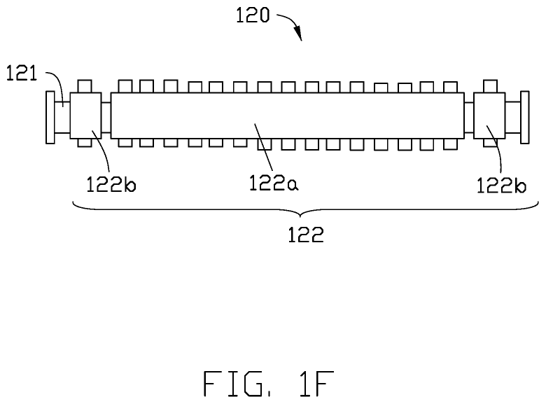

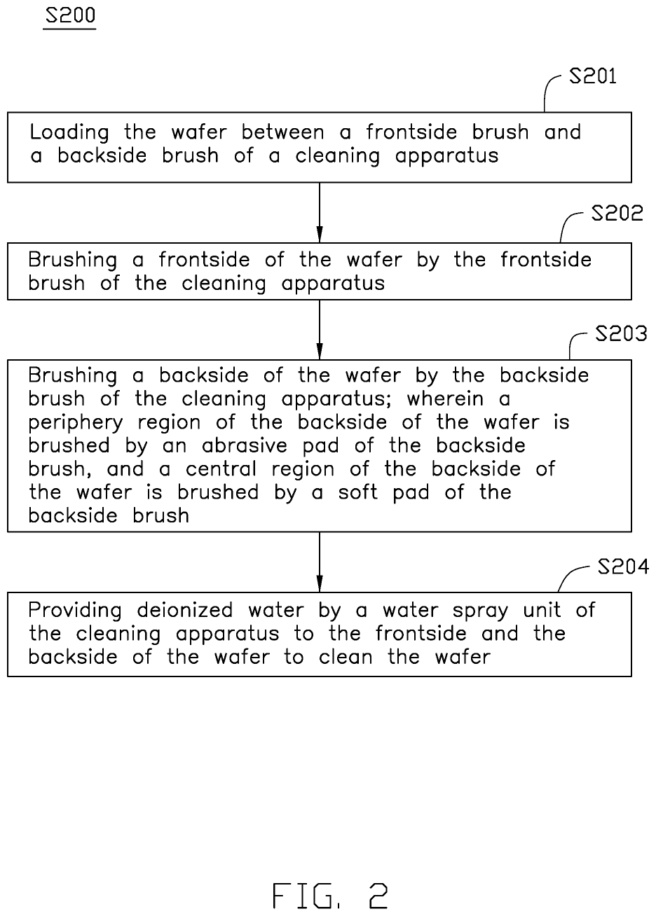

The description will be made as to the exemplary implementations of the present disclosure in conjunction with the accompanying drawings in FIGS. 1A through 2. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1A, a schematic diagram of a cleaning apparatus 100 for cleaning a wafer 100 according to an implementation of the present disclosure is illustrated. The cleaning apparatus 100 is a double sided scrubber. The cleaning apparatus 100 is used to clean the wafer W after a chemical mechanical polishing (CMP) process. In the cleaning apparatus 100, the wafer W is scrubbed simultaneously on both a frontside and a backside by brushes. The frontside of the wafer W includes a surface of the wafer W that is being processed (such as a surface that is planarized in the CMP process); and the backside of the wafer W includes a surface of the wafer W that is opposite to the processed surface. After the CMP process, the frontside and the backside of the wafer W are covered by slurry residues including materials of a polishing slurry and materials (e.g., particles) of the wafer W that are removed by the CMP process. The slurry residues on the wafer W must be cleaned before subsequent processing of the wafer W to prevent contamination.

As shown in FIG. 1A, the cleaning apparatus 100 includes a frontside brush 110 for cleaning the frontside of the wafer W and a backside brush 120 for cleaning the backside of the wafer W. When the wafer W is cleaned, the wafer W is disposed between the frontside brush 110 and the backside brush 120. The backside brush 120 is beneath the wafer W and directly below the frontside brush 110. The cleaning apparatus 100 may further includes a brush motor 130, at least one roller 140, and one or more water spray units 150. The brush motor 130 is coupled to the frontside brush 110 and the backside brush 120 to rotate the frontside brush 110 and the backside brush 120. Each of the frontside brush 110 and the backside brush 120 is rotated about its central axis by the brush motor 130. The roller 140 is configured to be in contact with an outer edge of the wafer W to rotate the wafer W. A roller motor 160 is coupled to the roller 140 to rotate the roller 140. The rotary motion of the roller 140 is transferred to the wafer W when an edge of the roller 140 comes into contact with the outer edge of the wafer W. As shown in FIG. 1A, two rollers 140 and 140a may be used to rotate the wafer W so that the entire wafer may be cleaned. The water spray units 150 are configured to supply deionized water to clean the wafer W.

Referring to FIG. 1B, a schematic diagram showing the frontside brush 110 and the backside brush 120 of the cleaning apparatus 100 is illustrated. Referring to FIG. 1C, a schematic diagram of the backside of the wafer W is illustrated. Referring to FIGS. 1D and 1E, exploded views of the frontside brush 110 and the backside brush 120 of FIG. 1B are illustrated. Referring to FIG. 1F, a schematic diagram of the backside brush 120 according to another implementation is illustrated.

As shown in FIG. 1B, the frontside brush 110 of the cleaning apparatus 100 includes a frontside brush core 111 and a frontside brush pad 112. The frontside brush core 111 is coupled to the brush motor 130 to rotate the frontside brush 110 along its central axis. The frontside brush pad 112 covers an outer surface of the frontside brush core 111. The frontside brush pad 112 may include polyvinyl alcohol (PVA). The frontside brush pad 112 includes a plurality of protrusions configured to make contact with the frontside of the wafer W.

As shown in FIG. 1C, the backside of the wafer has a central region W2 and a periphery region W1 surrounding the central region W2. After a CMP process, most of the slurry residues are accumulated at the backside of the wafer W. Particularly, metal particles or carbon particles in the slurry residues are likely to be attached at the periphery region W1 of the backside of the wafer W. The metal particles or carbon particles are hard to remove by the PVA brushes. Usually, an additional chemical cleaning process is required to remove the metal particles or carbon particles attached at the periphery region W1 of the backside of the wafer. The backside brush 120 includes a backside brush core 121 and a backside brush pad 122 covering an outer surface of the backside brush core 121 for brushing the backside of the wafer W. The backside brush pad 122 includes a soft pad 122a and an abrasive pad 122b.

The soft pad 122a covers a portion of the outer surface of the backside brush core 121 and configured to brush the central region W2 of the backside of the wafer W. The abrasive pad 122b covers another portion of the outer surface of the backside brush core 121 and configured to brush the periphery region W1 of the backside of the wafer W. The hardness of the soft pad 122a of the backside brush pad 122 is lower than the hardness of the abrasive pad 122b of the backside brush pad 122. The soft pad 122a of the backside brush pad 122 may be made of PVA. The abrasive pad 122b of the backside brush pad 122 may be made of materials such as sand papers, polyurethane, non-woven fabrics, asbestos, or any combination thereof. The soft pad 122a of the backside brush pad 122 includes a plurality of soft protrusions configured to make contact with the central region W of the backside of the wafer W. The abrasive pad 122b of the backside brush pad 122 includes a plurality of abrasive protrusions configured to make contact with the periphery region W1 of the backside of the wafer W. The backside brush core 121 has a a cylindrical shape. As shown in FIG. 1B, the abrasive pad 122b of the backside brush pad 122 is disposed at one end of the backside brush core 121, and the soft pad 122a of the backside brush pad 122 is disposed at another portion of the backside brush core 121. In some implementations, the abrasive pad 122b of the backside brush pad 122 has two portions respectively disposed at the ends of the backside brush core 121, and the soft pad 122a is disposed at the middle portion of the backside brush core 121.

When the backside brush 120 is brushing the backside of the wafer W, the soft pad 122a of the backside brush pad 122 brushes the central regions W2 of the backside of the wafer W, and the abrasive pad 122b of the backside brush pad 122 brushes the periphery region W1 of the backside of the wafer W. The abrasive pad 122b of the backside brush pad 122 has a higher hardness than that of the soft pad 122a. The metal particles or carbon particles attached at the periphery region W1 of the backside of the wafer W can be removed by the abrasive pad 122b. No additional chemical cleaning process is required to clean the periphery regions W1 of the backside of the wafer W. Therefore, the backside brush 120 can improve the performance of the cleaning process.

Referring to FIG. 2, a flowchart of a method S200 of cleaning a wafer is illustrated. As shown in FIG. 2, the method S200 includes actions S201 to S204. In action S201, a wafer is loaded between a frontside brush and a backside brush of a cleaning module. The cleaning module may correspond to the cleaning apparatus 100 illustrated in FIGS. 1A through 1F. The wafer W has a frontside and a backside. The frontside of the wafer W includes a surface of the wafer W that is being processed (such as a surface that is planarized in a chemical mechanical polishing (CMP) process). The backside of the wafer W includes a surface of the wafer W that is opposite to the processed surface. The frontside of the wafer W is in contact with the frontside brush 110 of the cleaning apparatus 100, and the backside of the wafer W is in contact with the backside brush 120 of the cleaning apparatus 100. The cleaning apparatus 100 may further includes the brush motor 130, at least one roller 140, and one or more water spray units 150.

In action S202, the frontside of the wafer W is brushed by the frontside brush 110 of the cleaning apparatus 100. In action S203, the backside of the wafer W is brushed by the backside brush 120 of the cleaning apparatus 100. The brush motor 130 is coupled to the frontside brush 110 and the backside brush 120 to rotate the frontside brush 110 and the backside brush 120. Each of the frontside brush 110 and the backside brush 120 is rotated about its central axis by the brush motor 130. The roller 140 is in contact with an outer edge of the wafer W to rotate the wafer W. The roller motor 160 is coupled to the roller 140 to rotate the roller 140. The rotary motion of the roller 140 is transferred to the wafer W when an edge of the roller 140 comes into contact with the outer edge of the wafer W. The wafer W is rotated by the roller 140 so that the entire wafer W may be cleaned. The frontside brush 110 of the cleaning apparatus 100 includes the frontside brush core 111 and the frontside brush pad 112. The frontside brush core 111 is coupled to the brush motor 130 to rotate the frontside brush 110 along its central axis. The frontside brush pad 112 covers the outer surface of the frontside brush core 111. The frontside brush pad 112 may include polyvinyl alcohol (PVA). The frontside brush pad 112 includes a plurality of protrusions configured to make contact with the frontside of the wafer W.

The backside of the wafer has the central region W2 and the periphery region W1 surrounding the central region W2. The backside brush 120 includes the backside brush core 121 and the backside brush pad 122 covering the outer surface of the backside brush core 121 for brushing the backside of the wafer W. The backside brush pad 122 includes the soft pad 122a and the abrasive pad 122b. The soft pad 122a covers a portion of the outer surface of the backside brush core 121. The central region W2 of the backside of the wafer W is brushed by the soft pad 122a of the backside brush 120. The abrasive pad 122b covers another portion of the outer surface of the backside brush core 121. The periphery region W1 of the backside of the wafer W is brushed by the abrasive pad 122b of the backside brush 120.

The hardness of the soft pad 122a of the backside brush pad 122 is lower than the hardness of the abrasive pad 122b of the backside brush pad 122. The soft pad 122a of the backside brush pad 122 may include PVA. The abrasive pad 122b of the backside brush pad 122 may be made of materials selected from sand papers, polyurethane, non-woven fabrics, asbestos, or any combination thereof. The soft pad 122a of the backside brush pad 122 includes a plurality of soft protrusions configured to make contact with the central region W of the backside of the wafer W. The abrasive pad 122b of the backside brush pad 122 includes a plurality of abrasive protrusions configured to make contact with the periphery region W1 of the backside of the wafer W. The backside brush core 121 has a cylindrical shape (e.g., a cylindrical rod). In some implementations, the abrasive pad 122b of the backside brush pad 122 is disposed at one end of the backside brush core 121, and the soft pad 122a of the backside brush pad 122 is disposed at another portion of the backside brush core 121. In some implementations, the abrasive pad 122b of the backside brush pad 122 has two portions respectively disposed at the ends of the backside brush core 121, and the soft pad 122a is disposed at the middle portion of the backside brush core 121. The abrasive pad 122b of the backside brush pad 122 has a higher hardness that that of the soft pad 122a. Metal particles or carbon particles attached at the periphery region W1 of the backside of the wafer W after a CMP process can be removed by the abrasive pad 122b. No additional chemical cleaning process is required to clean the periphery regions W1 of the backside of the wafer W. Therefore, the backside brush 120 can improve the performance of the cleaning process.

In action S204, the water spray units 150 of the cleaning apparatus 100 may provide deionized water to the frontside and the backside of the wafer W to clean the wafer W. For example, each of water spray units 150 may spray (or pressurized spray) deionized water to the surfaces of the wafer W through a nozzle that is connected to a water supply via a water tube.

According to yet another implementation, the present disclosure also provides a backside brush for cleaning a backside of a wafer. The backside brush may correspond to the backside brush 120 illustrated in FIGS. 1A through 1F. The backside of the wafer W has the central region W2 and the periphery region W1 surrounding the central region W2. The backside brush 120 includes the backside brush core 121 and the backside brush pad 122 covering the outer surface of the backside brush core 121 for brushing the backside of the wafer W. The backside brush pad 122 includes the soft pad 122a and the abrasive pad 122b. The soft pad 122a covers a portion of the outer surface of the backside brush core 121 and configured to brush the central region W2 of the backside of the wafer W. The abrasive pad 122b covers another portion of the outer surface of the backside brush core 121 and configured to brush the periphery region W1 of the backside of the wafer W. The hardness of the soft pad 122a of the backside brush pad 122 is lower than the hardness of the abrasive pad 122b of the backside brush pad 122. The soft pad 122a of the backside brush pad 122 may include PVA. The abrasive pad 122b of the backside brush pad 122 may be made of materials selected from sand papers, polyurethane, non-woven fabrics, asbestos, or a combination thereof.

As describe above, the backside brush of the cleaning apparatus of the implementations of the present disclosure includes a soft pad for cleaning a central region of a backside of a wafer and an abrasive pad for cleaning a periphery region of the backside of the wafer. Metal particles and carbon particles attached to the periphery region of the backside of the wafer after manufacturing processes (such as chemical mechanical polishing or etching) can be removed by the abrasive pad of the backside brush of the present disclosure without further chemical cleaning processes. The backside brush of the present disclosure can improve the performance of the cleaning process for the wafer.

The implementations shown and described above are only examples. Many details are often found in the art such as the other features of a backside brush for cleaning a wafer and a cleaning apparatus having the same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A backside brush for cleaning a backside of a wafer, wherein the backside of the wafer has a central region and a periphery region surrounding the central region, the backside brush comprising:
a backside brush core; and
a backside brush pad covering an outer surface of the backside brush core for brushing the backside of the wafer, the backside brush pad comprising:
a soft pad covering a portion of the outer surface the backside brush core and configured to brush the central region of the backside of the wafer; and
an abrasive pad covering another portion of the outer surface of the backside brush core and configured to brush the periphery region of the backside of the wafer.

2. The backside brush of claim 1, wherein the soft pad of the backside brush pad is made of polyvinyl alcohol (PVA).

3. The backside brush of claim 1, wherein the abrasive pad of the backside brush pad includes at least one of sand papers, polyurethane, non-woven fabrics, and asbestos.

4. The backside brush of claim 1, wherein a hardness of the soft pad of the backside brush pad is lower than a hardness of the abrasive pad of the backside brush pad.

5. The backside brush of claim 1, wherein the soft pad of the backside brush pad comprises a plurality of soft protrusions configured to make contact with the central region of the backside of the wafer.

6. The backside brush of claim 1, wherein the abrasive pad of the backside brush pad comprises a plurality of abrasive protrusions configured to make contact with the periphery region of the backside of the wafer.

7. The backside brush of claim 1, wherein the backside brush core has a shape of a cylindrical rod, and the abrasive pad of the backside brush is disposed at one end of the backside brush core.

8. The backside brush of claim 1, wherein the backside brush core has a shape of a cylindrical rod, and the abrasive pad of the backside brush has two portions respectively disposed at two ends of the backside brush core.

9. A cleaning apparatus for cleaning a wafer, the cleaning apparatus comprising:
a frontside brush for cleaning a frontside of the wafer, the frontside brush comprising a frontside brush core and a frontside brush pad covering an outer surface of the frontside brush core; and
a backside brush for cleaning a backside of the wafer, wherein the backside of the wafer has a central region and a periphery region surrounding the central region, and the backside brush comprising:
a backside brush core; and
a backside brush pad covering an outer surface of the backside brush core for brushing the backside of the wafer, the backside brush pad comprising:
a soft pad covering a portion of the outer surface of the backside brush core, wherein the soft pad is configured to brush the central region of the backside of the wafer; and
an abrasive pad covering another portion of the outer surface of the backside brush core, wherein the abrasive pad is configured to brush the periphery region of the backside of the wafer.

10. The cleaning apparatus of claim 9, wherein the frontside brush pad is made of polyvinyl alcohol (PVA), and comprises a plurality of protrusions configured to make contact with the frontside of the wafer.

11. The cleaning apparatus of claim 9, wherein the soft pad of the backside brush pad is made of polyvinyl alcohol (PVA), and comprises a plurality of soft protrusions configured to be in contact with the central region of the backside of the wafer.

12. The cleaning apparatus of claim 9, wherein the abrasive pad of the backside brush pad comprises a plurality of abrasive protrusions configured to be in contact with the periphery region of the backside of the wafer, and includes at least one of sand papers, polyurethane, non-woven fabrics, and asbestos.

13. The cleaning apparatus of claim 9, wherein a hardness of the soft pad of the backside brush pad is lower than a hardness of the abrasive pad of the backside brush pad.

14. The cleaning apparatus of claim 9, wherein the backside brush core has a shape of a cylindrical rod, and the abrasive pad of the backside brush pad is disposed at one end of the backside brush core.

15. The cleaning apparatus of claim 9, wherein the backside brush core has a shape of a cylindrical rod, and the abrasive pad of the backside brush pad has two portions respectively disposed at two ends of the backside brush core.

16. The cleaning apparatus of claim 9, further comprising a brush motor coupled to the frontside brush and the backside brush to rotate the frontside brush and the backside brush.

17. The cleaning apparatus of claim 9, further comprising at least one roller configured to make contact with an outer edge of the wafer and rotate the wafer.

18. The cleaning apparatus of claim 9, further comprising a water spray unit configured to supply deionized water to the wafer.

19. A method of cleaning a wafer, comprising:
loading the wafer between a frontside brush and a backside brush of a cleaning apparatus;
brushing a frontside of the wafer by the frontside brush of the cleaning apparatus;
brushing a backside of the wafer by the backside brush of the cleaning apparatus, wherein a periphery region of the backside of the wafer is brushed by an abrasive pad of the backside brush, and a central region of the backside of the wafer is brushed by a soft pad of the backside brush; and
providing deionized water by a water spray unit of the cleaning apparatus to the frontside and the backside of the wafer to clean the wafer.

20. The method of claim 19, wherein a hardness of the soft pad of the backside brush pad is lower than a hardness of the abrasive pad of the backside brush pad.
